(19) United States
(12) Patent Application Publication
(10) Pub. No.: US 2017/0343712 A1
(43) Pub. Date: Nov. 30, 2017

(54) A POLARIZED LIGHT EMISSIVE DEVICE

(71) Applicant: MERCK PATENT GMBH, Darmstadt (DE)

(72) Inventors: Masaki HASEGAWA, Kanagawa (JP); Noriyuki MATSUDA, Chiba (JP)

(73) Assignee: MERCK PATENT GMBH, Darmstadt (DE)

(21) Appl. No.: 15/536,424

(22) PCT Filed: Nov. 18, 2015
(86) PCT No.: PCT/EP2015/002308

§ 371 Date: Jun. 15, 2017

(30) Foreign Application Priority Data
Dec. 15, 2014 (EP) 14004226.8

(51) Int. Cl. G02B 5/30; B32B 3/30; H01L 51/52; G02F 2/02; B82Y 20/00; C23C 18/00

(52) U.S. Cl. CPC G02B 5/30; H01L 51/5293; H01L 51/5281; G02F 2/02; B32B 3/30; C23C 18/00; B82Y 20/00; G02F 2202/36

(57) ABSTRACT

The present invention relates to a polarized light emissive device and a method for its manufacture comprising a plural of fluorescent semiconductor quantum rods, and to a preparation thereof. The invention further relates to a use of the polarized light emissive device in optical devices, and to an optical device comprising the polarized light emissive device.

### FIELD OF THE INVENTION

The present invention relates to a polarized light emissive device comprising a plural of fluorescent semiconductor quantum rods, and to a preparation thereof. The invention further relates to a use of the polarized light emissive device in optical devices, and to an optical device comprising the polarized light emissive device.

### BACKGROUND ART

Polarization properties of light are used in a variety of optical applications ranging from liquid-crystal displays to microscopy, metallurgy inspection and optical communications.

For example, international patent application laid-open No. WO 2012/059931A1 , W02010/089743 A1, and WO 2010/095140 A2, Tibert van der Loop, Master thesis for Master of Physical Sciences FNWI Universiteit van Amsterdam Roeterseiland Complex; Nieuwe achtergracht 166 1018WV Amsterdam, M. Bashouti et. al., “ChemPhysChem” 2006, 7, p. 102-p. 106, M. Mohannadimasoudi et. al., Optical Materials Express 3, Issue 12, p. 2045-p. 2054 (2013), Tie Wang et al., “Self-Assembled Colloidal Superparticles from Nanorods”, Science 338 358 (2012), Yorai Amit et. al., “Semiconductor nanorods layers aligned through mechanical rubbing” Phys. Status Solidi A 209, No. 2, 235-242.

Further, a full color quantum dot display by transfer patterning is known in the art, Byoung Lyong Choi et. al., “Pick-and-Place transfer of quantum dot for full-color display” IDW '13 pp. 1378-1381.

### PATENT LITERATURE

1. WO 2012/059931 A1

2. WO 2010/089743 A1

3. WO 2010/095140 A2

### NON PATENT LITERATURE

4. Tibert van der Loop, Master thesis for Master of Physical Sciences FNWI Universiteit van Amsterdam Roeterseiland Complex; Nieuwe achtergracht 166 1018WV Amsterdam

5. M. Bashouti et. al., “ChemPhysChem” 2006, 7, p. 102 -p. 106,

6. M. Mohannadimasoudi et. al., Optical Materials Express 3, Issue 12, p. 2045-p. 2054 (2013),

7. Tie Wang et al., “Self-Assembled Colloidal Superparticles from Nanorods”, Science 338 358 (2012)

8. Byoung Lyong Choi et. al., “Pick-and-Place transfer of quantum dot for full-color display” IDW '13 pp. 1378-1381

9. Yorai Amit et. al., “Semiconductor nanorods layers aligned through mechanical rubbing” Phys. Status Solidi A 209, No. 2, 235-242

### SUMMARY OF THE INVENTION

However, the inventors newly have found that there is still one or more of considerable problems for which improvement is desired, as listed below.
1. A polarized light emissive device comprising at least 1^{st} and 2^{nd} sub color areas, in which capable to emit polarized light from each sub color areas is desired to realize various polarized light emisstion from the polarized light emissive device.
2. Simple & easier fabrication process for preparing said polarized light emissive device to reduce production cost and/or production step is needed.
3. New fabrication process for preparing said polarized light emissive device to decrease waste ratio of the inorganic fluorescent semiconductor quantum rods used in a fabrication process is desired.

The inventors aimed to solve the all aforementioned problems. Surprisingly, the inventors have found a novel polarized light emissive device (100), comprising a substrate (110), and a plural of inorganic fluorescent semiconductor quantum rods (120) directly aligned on the surface of the substrate in a common direction without a binder or matrix, in which the polarized light emissive device embraces one or more of first sub color areas and one or more of second sub color areas (130), solves the problems 1 to 3 at the same time.

Further advantages of the present invention will become evident from the following detailed description.

In another aspect, the invention relates to use of the said polarized light emissive device (100) in an optical device.

In another aspect, the invention further relates to an optical device (170), wherein the optical device (170) includes a polarized light emissive device (100), comprising a substrate (110), and a plural of inorganic fluorescent semiconductor quantum rods (120) directly aligned on the surface of the substrate in a common direction without a binder or matrix, in which the polarized light emissive device embraces one or more of first sub color areas and one or more of second sub color areas (130).

The present invention also provides for a method for preparing the said polarized light emissive device (100), wherein the method comprises the following sequential steps of:
(a) dispersing a plural of inorganic fluorescent semiconductor quantum rods into a solvent;
(b) providing the resulting solution from step (a) onto a plural of grooves of a polymer substrate; and
(c) transferring the plural of inorganic fluorescent semiconductor quantum rods onto the surface of a substrate or a transfer material, and optionally transferring from the transfer material to a substrate.

### DESCRIPTION OF DRAWINGS

FIG. 1: shows a schematic view of one embodiment of a polarized light emissive device (100).

FIG. 2: shows schematic view of another embodiment of the polarized light emissive device (100).

FIG. 3: shows schematic view of another embodiment of the polarized light emissive device (100).

FIG. 4: shows schematic view of a transferring process of the plural of inorganic fluorescent semiconductor quantum rods (120) in the working example 1.

FIG. 5: shows schematic view of a transferring process of the plural of inorganic fluorescent semiconductor quantum rods (120) in the working example 2.

FIG. 6: shows schematic view of another embodiment of transferring process of the plural of inorganic fluorescent semiconductor quantum rods (120).

FIG. 7: shows schematic view of another embodiment of transferring process of the plural of inorganic fluorescent semiconductor quantum rods (120).

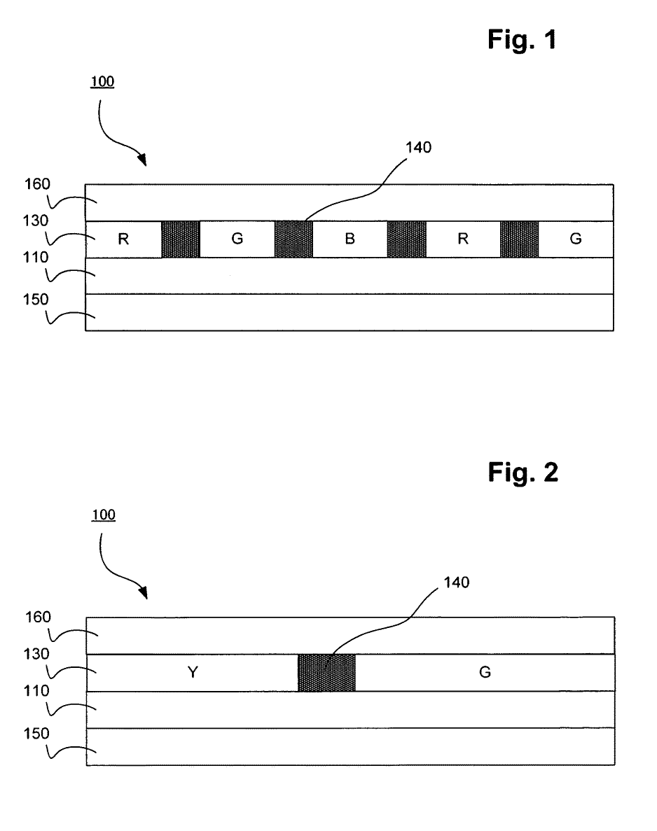

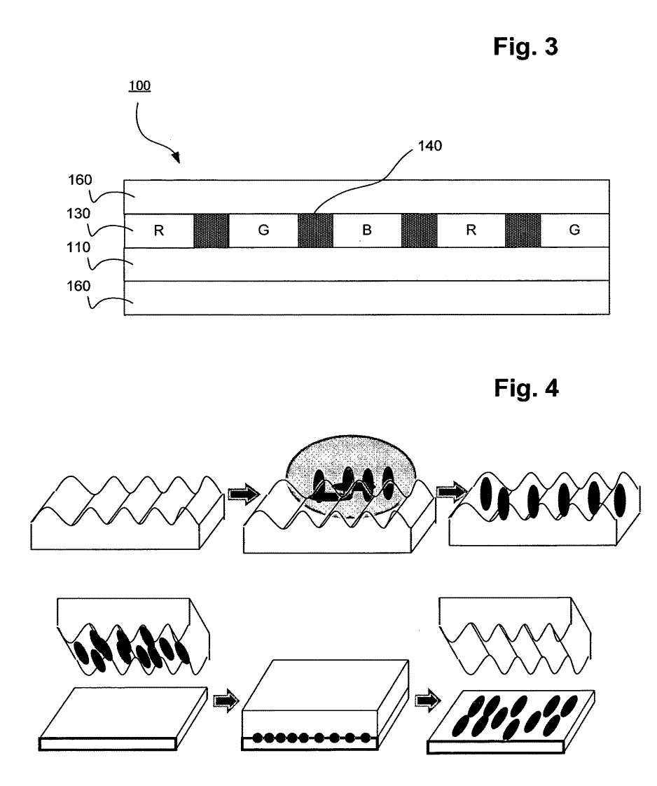

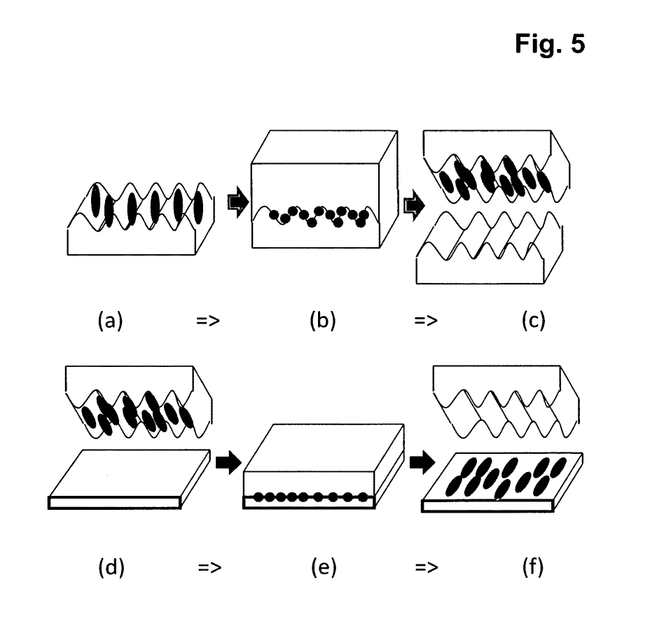

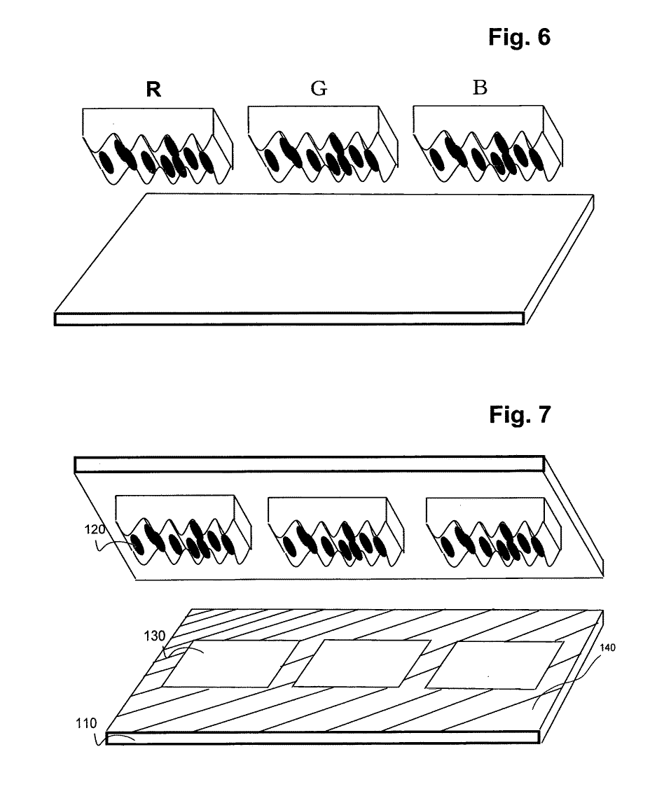

### LIST OF REFERENCE SIGNS IN FIG. 1

100. a polarized light emissive device
110. a substrate
120. a plural of inorganic fluorescent semiconductor quantum rods (not shown in the FIG. 1)
130. sub color areas
140. a light shielding area (optional)
150. a light reflection medium (optional)
160. a transparent passivation medium (optional)

### DETAILED DESCRIPTION OF THE INVENTION

In a general aspect, a polarized light emissive device (100), comprising a substrate (110), and a plural of inorganic fluorescent semiconductor quantum rods (120) directly aligned on the surface of the substrate in a common direction without a binder or matrix, in which the polarized light emissive device embraces one or more of first sub color areas and one or more of second sub color areas (130).

Average of orientation dispersion of the long axis of the plural of inorganic fluorescent semiconductor quantum rods (120) directly aligned on the surface of each sub color areas of the polarized light emissive device (100) can be determined by a polarization ratio of light emittion from each sub color area of the device (100).

The polarization ratio of each sub color areas of the polarized light emissive device (100) of the present invention can be measured by a polarization microscope equipped with spectrometer. For example, the plural of inorganic fluorescent semiconductor quantum rods (120) directly aligned on the surface of each sub color areas of the polarized light emissive device (100) is excited by light source such as a 1 W, 405 nm light emitting diode, and the light emission from the sub color areas of the polarized light emissive device (100) is observed by a microscope with a 10 times objective lens. By using mask, just targeted sub color areas can be excited by light source to measure. The light from the objective lens is introduced to the spectrometer throughout a long pass filter, which can cutoff the light emission from the light source, such as 405 nm wavelength light, and a polarizer.

The light intensity of the peak emission wavelength polarized parallel and perpendicular to the average axis of the fibers of the each film is observed by the spectrometer. Polarization ratio of each sub color area (hereafter “PRs” for short) of light emission is determined from the equation formula I.

Equation formula I

PRs={(Intensity of Emission)_{//}−(Intensity of Emission)⊥}/ {(Intensity of Emission)_{//}+(Intensity of Emission)⊥}

In a preferred embodiment of the present invention, value of PR is at least 0.1

More preferably, at least 0.4, even more preferably, at least 0.5 or more.

Preferably, each sub color pixels of the polarized light emissive device (100) emits visible light when it is illuminated by light source.

In general, the substrate (110) can be flexible, semi-rigid or rigid. The material for a substrate (110) is not particularly limited.

In a preferred embodiment of the invention, said substrate (110) is transparent.

Generally, the thickness of the substrate (110) of the polarized light emissive device (100) may be varied as desired.

In some embodiments, the substrate (110) can have a thickness of at least 0.1 mm and/or at the most 10 cm.

Preferably, from 0.2 mm to 5 mm

More preferably, as a transparent substrate, a transparent polymer substrate, glass substrate, thin glass substrate stacked on a transparent polymer film, transparent metal oxides (for example, oxide silicone, oxide aluminum, oxide titanium), can be used.

According to the present invention, a transparent polymer substrate can be made from polyethylene, ethylene-vinyl acetate copolymer, ethylene-vinylalcohol copolymer, polypropylene, polystyrene, polymethyl methacrylate, polyvinylchloride, polyvinylalcohol, polyvinylvutyral, nylon, polyether ether ketone, polysulfone, polyether sulfone, tetrafluoroethylene-erfluoroalkylvinyl ether copolymer, polyvinylfluoride, tetraflyoroethylene ethylene copolymer, tetrafluoroethylene hexafluoro polymer copolymer, or a combination of any of these.

According to the present invention, preferably, the plural of inorganic fluorescent semiconductor quantum rods (120) is selected from the group consisting of II-VI, III-V, or IV-VI semiconductors and a combination of any of these.

More preferably, inorganic fluorescent semiconductor quantum rods can be selected from the groups consisting of CdS, CdSe, CdTe, ZnS, ZnSe, ZnTe, No, GaAs, Gap, GaAs, Gas, Hags, HgSe, HgSe, HgTe, InAs, InP, InSb, AlAs, AlP, AlSb, Cu₂S, Cu₂Se, CuInS2, CuInSe₂, Cu₂(ZnSn)S₄, Cu₂(InGa)S₄, TiO₂ alloys and a combination of any of these.

For example, for red emission use, CdSe rods, CdSe dot in CdS rod, ZnSe dot in CdS rod, CdSe/ZnS rods, InP rods, CdSe/CdS rods, ZnSe/CdS rods or combination of any of these. For green emission use, such as CdSe rods, CdSe/ZnS rods, or combination of any of these, and for blue emission use, such as ZnSe, ZnS, ZnSe/ZnS core shell rods, or combination of any of these.

Examples of inorganic fluorescent semiconductor quantum rods have been described in, for example, the international patent application laid-open No. WO2010/095140A.

In a preferred embodiment of the invention, the length of the overall structures of the inorganic fluorescent semiconductor quantum rods is from 8 nm to 500 nm. More preferably, from 10 nm to 160 nm. The overall diameter of the said inorganic fluorescent semiconductor quantum rods is in the range from 1 nm to 20 nm. More particularly, from 1 nm to 10 nm.

In a preferred embodiment of the present invention, the plural of the inorganic fluorescent semiconductor quantum rods comprises a surface ligand.

The surface of the inorganic fluorescent semiconductor quantum rods can be over coated with one or more kinds of surface ligands.

Without wishing to be bound by theory it is believed that such a surface ligands may lead to disperse the inorganic fluorescent semiconductor quantum rods in a solvent more easily.

The surface ligands in common use include phosphines and phosphine oxides such as Trioctylphosphine oxide (TOPO), Trioctylphosphine (TOP), and Tributylphosphine (TBP); phosphonic acids such as Dodecylphosphonic acid (DDPA), Tridecylphosphonic acid (TDPA), Octadecylphosphonic acid (ODPA), and Hexylphosphonic acid (HPA); amines such as Dedecyl amine (DDA), Tetradecyl amine (TDA), Hexadecyl amine (HDA), and Octadecyl amine (ODA), thiols such as hexadecane thiol and hexane thiol; mercapto carboxylic acids such as mercapto propionic acid and mercaptoundecanoicacid; and a combination of any of these.

Examples of surface ligands have been described in, for example, the international patent application laid-open No. WO 2012/059931A.

Thus, in some embodiments of the present invention, the plural of inorganic fluorescent semiconductor quantum rods (120) is selected from the group consisting of II-VI, III-V, or IV-VI semiconductors and a combination of any of these, and wherein the plural of inorganic fluorescent semiconductor quantum rods (120) comprises a surface ligand.

According to the present invention, all sub color areas such as the first and second sub color areas of the polarized light emissive device (100) can be same sub color area. For example, as same sub color area, a plural of blue sub color areas, a plural of green, yellow, pink, or red sub color areas.

In some embodiments of the present invention, the first sub color areas emit polarized light having longer peak wavelength than the second sub color areas when it is exited.

Preferably, the first and the second sub color areas can be the combination of sub color areas selected from the group consisting of blue, blue-green, green, yellow, pink, orange and red.

Preferably, the sub color areas (130) comprise red sub color, green sub color and blue sub color areas. Or the sub color areas (130) can be the combination of blue sub color area and yellow or red sub color area. Each single sub color area comprises a plural of inorganic fluorescent semiconductor quantum rods (120) which emits light of each single color when it is exited, preferably.

In some embodiments of the present invention, the polarized light emissive device (100) comprises one or more of red sub color areas, green sub color areas and blue sub color areas.

In a preferred embodiment of the present invention, the polarized light emissive device (100) mainly consists of red sub color areas, green sub color areas and blue sub color areas to realize RGB full color polarized light emitting device.

According to the present invention, an average alignment direction of the plural of inorganic fluorescent semiconductor quantum rods (120) aligned directly on the surface of the first sub color areas can be same or different. By changing transferring direction of the plural of inorganic fluorescent semiconductor quantum rods to the substrate, it can be fabricated.

For example, after a transfer material having a plural of inorganic fluorescent semiconductor quantum rods pealed off from a substrate having a plural of grooves on the surface, then, the transfer is rotated to the desired direction with well known technique, then, the transfer is faced to a substrate to transfer the quantum rods to the substrate.

Without wishing to be bound by theory it is believed that such a differenciation may lead to various polarized light emittion from the polarized light emissive device (100).

Thus, in some embodiments, an average alignment direction of the plural of inorganic fluorescent semiconductor quantum rods (120) aligned directly on the surface of the first sub color areas is different from an average alignment direction of the plural of inorganic fluorescent semiconductor quantum rods (120) aligned directly on the surface of the second sub color areas.

According to the present invention, the term “different” means at least 5% difference of the average alignment direction or more.

In some embodiments of the present invention, optionally, the polarized light emissive device (100) further comprises light shielding areas' (140).

In a preferred embodiment, the light shielding area is placed in between the sub color areas like described in FIG. 1.

Preferably, the light shielding area is a black matrix (BM).

In other words, sub color areas of the present invention can be marked out by one or more of the light shielding area, such as by black matrix.

A material for the light shielding are is not particularly limited. Well known materials, especially well known BM materials for color filters can be used preferably as desired. Such as black dye dispersed polymer composition, like described in JP 2008-260927A, WO 2013/031753A.

Fabrication method of the light shielding area is not particularly limited, well known techniques can be used in this way. Such as, direct screen printing, photolithography, vapor deposition with mask.

In some embodiments, optionally, the polarized light emissive device (100) further comprises a light reflection medium (150). In a preferred embodiment, the light reflection medium (150) is a light reflection layer.

According to the present invention, the term “layer” includes “sheet” like structure.

In a preferred embodiment of the present invention, the light reflection medium (150) can be placed on the outmost surface of the substrate, or in the substrate.

According to the present invention, the term “light reflection” means reflecting at least around 60% of incident light at a wavelength or a range of wavelength used during operation of a polarized light emissive device. Preferably, it is over 70%, more preferably, over 75%, the most preferably, it is over 80%.

More preferably, the light reflection medium (150) is placed on opposite side of the surface from the surface that a plural of inorganic fluorescent semiconductor quantum rods (120) is directly aligned on. A structure and/or material for the light reflection medium (150) is not particularly limited. Well known light reflection structures and/or materials for a light reflection medium can be used preferably as desired.

According to the present invention, the light reflection medium (150) can be single layer or multiple layers.

In a preferred embodiment, the light reflection medium (150) is selected from the group consisting of Al layer, Al+MgF₂ stacked layers, Al+SiO stacked layers, Al+dielectric multiple layers, Au layer, and Cr+Au stacked layers; with the light reflection layer more preferably being Al layer, Al+MgF₂ stacked layers, or Al+SiO stacked layers.

In general, the methods of preparing the light reflection medium (150) can vary as desired and selected from well-known techniques.

The light reflection medium (150) can be prepared by a gas phase based coating process (such as sputtering, chemical vapor deposition, vapor deposition, flash evaporation), or a liquid-based coating process.

In some embodiments of the present invention, optionally, the polarized light emissive device (100) further comprises a transparent passivation medium (160).

Without wishing to be bound by theory it is believed that such a transparent passivation medium may lead to an increased protection of the plural of inorganic fluorescent semiconductor quantum rods (120) directly aligned on the surface of the substrate in a common direction without a binder or matrix.

Preferably, the transparent passivation medium (160) fully or partially covers the plural of inorganic fluorescent semiconductor quantum rods (120) directly aligned on the surface of the substrate (110) of the polarized light emissive device (100), or the substrate (110) having the plural of inorganic fluorescent semiconductor quantum rods (120) can be put between two transparent passivation films.

More preferably, the transparent passivation medium (160) fully covers the plural of inorganic fluorescent semiconductor quantum rods (120) like to encapsulate the plural of inorganic fluorescent semiconductor quantum rods in between the substrate (110) and the transparent passivation medium (160) or it can sandwich the substrate having the plural of inorganic fluorescent semiconductor quantum rods (120).

In general, the transparent passivation medium (160) can be flexible, semi-rigid or rigid.

The transparent material for the transparent passivation medium (160) is not particularly limited.

In a preferred embodiment, the transparent passivation medium (160) is selected from the groups consisting of a transparent polymer, transparent metal oxide (for example, oxide silicone, oxide aluminium, oxide titanium) as described above in the transparent substrate.

In general, the methods of preparing the transparent passivation medium can vary as desired and selected from well-known techniques.

In some embodiments, the transparent passivation medium (160) can be prepared by a gas phase based coating process (such as Sputtering, Chemical Vapor Deposition, vapor deposition, flash evaporation), or a liquid-based coating process.

In some embodiments, the polarized light emissive device (100) is illuminated by a light source. preferably, an UV, near UV, or blue light source, such as UV LED, near UV LED or blue LED, CCFL, EL, OLED, xenon lamp or a combination of any of these.

In one embodiment according to the present invention, the polarized light emissive device (100) can embrace one or more of the light sources.

For the purpose of the present invention, the term “near UV” is taken to mean a light wavelength between 300 nm and 410 nm.

In another aspect, the invention relates to use of the polarized light emissive device (100) in an optical device.

According to the present invention, the polarized light emissive device (100) can preferably be used as a polarized backlight unit such as a polarized LCD backlight unit, light emissive color filter for an optical device, optical communication device, or a q-rod display for example of indicator, or signboard.

In another aspect, the invention further relates to an optical device (170), wherein the optical device includes a polarized light emissive device (100), comprising a substrate (110), and a plural of inorganic fluorescent semiconductor quantum rods (120) directly aligned on the surface of the substrate in a common direction without a binder or matrix, in which the polarized light emissive device embraces one or more of first sub color areas and one or more of second sub color areas (130).

In a preferred embodiment of the present invention, the optical device (170) is selected from the group consisting of a polarized backlight unit such as a polarized LCD backlight unit, light emissive color filter for an optical device, optical communication device, q-rod display (such as indicator, signboard), microscopy, metallurgy inspection.

Examples of optical devices have been described in, for example, WO 2010/095140 A2 and WO 2012/059931 A1.

In another aspect, the polarized light emissive device (100) of the present invention can preferably be prepared with a liquid based coating process. The term “liquid-based coating process” means a process that uses a liquid-based coating composition.

Here, the term “liquid-based coating composition” embraces solutions, dispersions, and suspensions.

More specifically, the liquid-based coating process can be carried out with at least one of the following processes: Solution coating, ink jet printing, spin coating, dip coating, knife coating, bar coating, spray coating, roller coating, slot coating, gravure coating, flexographic printing, offset printing, relief printing, intaglio printing, or screen printing.

Therefore, the present invention further relates to a method for preparing the said polarized light emissive device (100), wherein the method comprises the following sequential steps of:

(a) dispersing a plural of inorganic fluorescent semiconductor quantum rods into a solvent;

(b) providing the resulting solution from step (a) onto a plural of microgrooves of a polymer substrate; and

(c) transferring the plural of inorganic fluorescent semiconductor quantum rods onto the surface of a substrate or a transfer material, and optionally transferring from the transfer material to a substrate.

In some embodiments of the present invention, optionally, the method further comprises following step (e) in step (c);

(e) giving a pressure to the substrate and moving the substrate toward the direction of the long axis of the plural of microgrooves of the polymer substrate under the pressure.

Without wishing to be bond by theory, it is believed that giving shear stress, caused by the step (e), to the transfer material and the plural of inorganic fluorescent semiconductor quantum rods (and/or the polymer substrate having fluorescent semiconductor quantum rods on the surface) may lead improved alignment of the plural of inorganic fluorescent semiconductor quantum rods.

Such shear stress can further be applied to the transfer material in step (c), when the transfer material is faced to a glass substrate to improve polarization ratio of the light emission from the polarized light emissive device.

In some embodiments of the present invention, optionally, the method further comprises following step (f) in step (b); (f) applying a sonification to a plural of inorganic fluorescent semiconductor quantum rods.

According to the present invention, preferably, step (e) and step (f) both can be applied in the fabrication process.

In some embodiments of the present invention, the method can further comprises the following steps;

(g) providing a solution having a plural of inorganic fluorescent semiconductor quantum rods onto a plural of microgrooves of a substrate, in which the plural of inorganic fluorescent semiconductor quantum rods in step (g) emits light having different peak wavelength from the plural of inorganic fluorescent semiconductor quantum rods used in step (a) when it is exited by excitation light from a light source; and

(h) transferring the plural of inorganic fluorescent semiconductor quantum rods onto the surface of a transfer material or the substrate of the polarized light emissive device (100).

In some embodiments of the present invention, as a preference, the plural of grooves is a plural of parallel microgrooves

According to the present invention, the term “microgrooves” means microsized or nanosized grooves.

In a preferred embodiment of the present invention, the axial pitch of the plural of grooves is from 10 nm to 1, 2 μm, and the height of the plural of grooves from bottom to top is from 10 nm to 1 μm. More preferably, the axial pitch is from 50 nm to 1 μm and the height is from 20 nm to 500 nm. Even more preferably, the axial pitch is from 260 nm to 420 nm and the height is from 50 nm to 100 nm.

In a preferred embodiment of the present invention, the plural of grooves on the surface of the substrate are placed periodically. Exemplary, the plural of grooves is placed on the surface of the substrate periodically and being parallel to the axis of grooves each other.

Fabrication method for the plural of microgrooves is not particularly limited. The plural of microgrooves can be fabricated as the integral part of the substrate, or can be fabricated separately and bonded onto the substrate with a transparent binder by publically known techniques. In a preferred embodiment of the present invention, a plural of microgrooves can be fabricated by laser light interference method.

Transparent materials such as transparent polymers, transparent metal oxides described above in substrate part can be used as the component of the plural of grooves preferably.

Example of laser light interference method has been described in, for example, the US patent application laid-open No. 2003/0017421.

The substrate including a plural of microgrooves is available, for example, from Edmund Optics Co., Koyo Co., Shinetsu Chemical Co. or Sigma-Aldrich.

According to the present invention, the solvent is water or an organic solvent.

The type of organic solvent is not particularly limited.

More preferably, purified water or the organic solvent which is selected from the group consisting of Methanol, Ethanol, Propanol, Isopropyl Alcohol, Buthl alcohol, Dimethoxyethane, Diethyl Ether, Diisopropyl Ether,

Acetic Acid, Ethyl Acetate, Acetic Anhydride, Tetrahydrofuran, Dioxane, Acetone, Ethyl Methyl Ketone, Carbon tetrachloride, Chloroform, Dichloromethane, 1.2-Dichloroethane, Benzene, Toluene, o-Xylene, Cyclohexane, Pentane, Hexane, Heptane, Acetonitrile, Nitromethane, Dimethylformamide, Triethylamine, Pyridine, Carbon Disulfide and a combination of any of these, can be used as the solvent. The most preferably, purified water or toluene.

Preferably, in step (a), dispersing is carried out with a mixer or ultrasonicator. A type of mixer or ultrasonicator is not particularly limited. In a further preferred embodiment, ultrasonicator is used in mixing, with preferably under air condition.

As a preference, in step (b), the resulting solution is coated onto the plural of microgrooves by the liquid—based coating process as described above to obtain a polarized light emissive device, with preferably under air condition.

In one embodiment of the present invention, after step (b) and before step (c), optionally, evaporation can be carried out by exposure in air condition at room temperature, baking, vacuum or a combination of any of these.

In case of evaporation is carried out by baking, the condition is of above 30° C. and under 200° C. preferably, even more preferably above 50° C. and under 90° C. in air condition to obtain a polarized light emissive device, with preferably under air condition.

The working examples 1-6 below provide descriptions of the polarized light emissive device of the present invention, as well as an in detail description of their fabrication.

### DEFINITION OF TERMS

According to the present invention, the term “transparent” means at least around 60% of incident light transmittal at the thickness used in a polarized light emissive device and at a wavelength or a range of wavelength used during operation of a polarized light emissive device.

Preferably, it is over 70%, more preferably, over 75%, the most preferably, it is over 80%.

The term “fluorescence” is defined as the physical process of light emission by a substance that has absorbed light or other electromagnetic radiation. It is a form of luminescence. In most cases, the emitted light has a longer wavelength, and therefore lower energy, than the absorbed radiation.

The term “semiconductor” means a material which has electrical conductivity to a degree between that of a conductor (such as copper) and that of an insulator (such as glass) at room temperature.

The term “inorganic ” means any material not containing carbon atoms or any compound that containing carbon atoms ionically bound to other atoms such as carbon monoxide, carbon dioxide, carbonates, cyanides, cyanates, carbides, and thiocyanates.

The term “emission” means the emission of electromagnetic waves by electron transitions in atoms and molecules.

Each feature disclosed in this specification, unless stated otherwise, may be replaced by alternative features serving the same, equivalent, or similar purpose. Thus, unless stated otherwise, each feature disclosed is but one example of a generic series of equivalent or similar features.

The invention is described in more detail in reference to the following examples, which are only illustrative and do not limit the scope of the invention.

### EXAMPLES

### Example 1: Fabrication of Polarized Light Emissive Device on a Flat Surface Glass Substrate with PDMS Sheet

0.003 g of polyethylenimine-covered rod-shaped CdS semiconductor nanocrystals (Qlight Technologies) were dispersed in water (3 g) by ultrasonication using Branson chip sonicator.

PDMS sheet having 1 um pitch and 100 nm height microgrooves (purchased from Shinetsu Chemical Co.) duplicated from the optical grating was cleaned by sonicating in ethanol.

The holographic grating consists of 5 mm glass substrate, epoxy resin with microgrooves fabricated by laser light interference, and aluminum reflector.

Then, the resulting solution was coated onto the optical grating by a drop casting method. 100 microliters of the resulting solution was dropped on the 25 mm×25 mm PDMS sheet having microgrooves, and covered the whole area of the grating uniformly.

Then, the water in the coated solution was evaporated at 80° C. for 10 minutes in air condition.

After water was evaporated, the nanocrystal coated surface of the PDMS sheet was faced to the glass substrate, and pressed to the glass substrate, then the PDMS sheet was removed from the glass substrate to transfer the nanocrystals to the glass substrate.

The aligned nanocrystals were successfully transferred to the glass substrate.

### Example 2: Fabrication of Polarized Light Emissive Device on Flat Surface Glass Substrate with PDMS Block

0.003 g of Tri-n-octylphosphine oxide (TOPO)-covered rod-shaped nanocrystals (Qlight Technologies) were dispersed in toluene (3 g) by ultrasonication using a chip sonicator (Branson Sonifier 250).

A holographic optical grating (purchased from Edmund Optics) having 260 nm pitch and 62.4 nm height microgrooves was cleaned by sonicating in acetone.

The holographic grating consists of 5 mm glass substrate, epoxy resin with microgrooves fabricated by laser light interference, and aluminum reflector.

Then, the resulting solution was coated onto the optical grating by a drop casting method. 100 microliters of the resulting solution was dropped onto the 25 mm×25 mm optical grating, and covered the whole area of the grating uniformly.

The toluene in the coated solution was evaporated at 20° C. for 5 minutes in air condition.

Polymerized PDMS block having a flat surface was faced to the nanocrystals coated optical grating and removed gently. The nanocrystals were transferred to the surface of the PDMS block. The PDMS block having nanocrystals on the surface was faced and contacted to a glass substrate having flat surface, then, the PDMS block was removed gently from the glass substrate. The nanocrystals were successfully transferred on the flat glass substrate.

### Example 3: Fabrication of Polarized Light Emissive Device on Flat Surface Glass Substrate with PDMS Block

0.003 g of Tri-n-octylphosphine oxide (TOPO)-covered rod-shaped semiconductor nanocrystals (Qlight Technologies) were dispersed in toluene (3 g) by ultrasonication using a chip sonicator (Branson Sonifier 250).

Four holographic optical gratings (purchased from Edmund Optics) having 1,200 line/mm microgrooves, 1,800 line/mm microgrooves, 2,400 line/mm microgrooves, and 3,600 line/mm microgrooves were each independently cleaned by sonicating in acetone.

The holographic gratings consists of 5 mm glass substrate, epoxy resin with microgrooves fabricated by laser light interference, and aluminum reflector, in this sequence.

Then, the resulting solution was coated onto the each optical grating by a drop casting method. 100 microliters of the resulting solution was dropped onto the 25 mm×25 mm each optical grating, and the dropped resulting solution covered the whole area of the grating uniformly. The toluene in the coated solution was evaporated at 20° C. for 5 minutes in air condition.

Four polymerized PDMS blocks having a flat surface were each independently faced to the each nanocrystals coated optical grating and removed gently. The nanocrystals were transferred to the surface of the PDMS blocks, each independently. Then, the each PDMS block having nanocrystals on the surface was faced and contacted to a glass substrate having flat surface, and removed gently from the glass substrate. The nanocrystals were successfully transferred on the flat glass substrates.

### Example 4: Fabrication of Polarized Light Emissive Device on Flat Surface Glass Substrate with PDMS Block

Polarized light emissive devices were fablicated in the same manner described in working example 3, expect for sonication was applied to the optical gratings during evaporation of the coated solution.

### Example 5: Fabrication of Polarized Light Emissive Device on Flat Surface Glass Substrate with PDMS Block

Polarized light emissive devices were fablicated in the same manner described in working example 3, expect for sonication was applied to the optical gratings during evaporation of the coated solution, and shear stress was also applied by hand when the each PDMS block was faced to the glass substrate.

The direction of the shear stress to the PDMS block was directed to the average alignment direction of the long axis of nanocrystals to the PDMS blocks

### Example 6: Evaluation of the Polarized Light Emissive Devices

The polarized light emissive devices fabricated in working examples 3 to 5 were evaluated by polarization microscope with spectrometer.

The each device was excited by a 1 W, 405 nm light emitting diode, and the each emission from the devices was observed by a microscope with a 10×objective lens. The light from the objective lens was introduced to the spectrometer through a long pass filter (420 nm nominal cutoff wavelength), and a polarizer. The objective of having the long pass filter in the evaluation system is to cut 405 nm excitation light. The light intensity of the peak emission wavelength polarized parallel and perpendicular to the microgrooves were observed by the spectrometer.

Spectrum of the emission of the polarized light emissive devices fabricated in the Example 3 to 5 was shown in table 1.

Polarization ratio (hereafter PR) of the emission was determined from the equation formula 1 (Eq. 1)

Equation formula 1

PR={(Intensity of Emission)_{//}−(Intensity of Emission)⊥}/ {(Intensity of Emission)_{//}+(Intensity of Emission)⊥}

TABLE 1
PR of the polarized light emissive devices.

| Microgrooves | Example | Sonication | Sonication + Shear Stress |
|---|---|---|---|
| [Line/mm] | 3 | (Example 4) | (Example 5) |
| 1,200 | 0.15 | 0.23 | 0.32 |
| 1,800 | 0.2 | 0.27 | 0.35 |
| 2,400 | 0.38 | 0.46 | 0.55 |
| 3,600 | 0.43 | 0.5 | 0.61 |

1. A polarized light emissive device (100), comprising a substrate (110), and a plural of inorganic fluorescent semiconductor quantum rods (120) directly aligned on the surface of the substrate in a common direction without a binder or matrix, in which the polarized light emissive device embraces one or more of first sub color areas and one or more of second sub color areas (130).

2. The polarized light emissive device (100) according to claim 1, wherein the first sub color areas emit polarized light having longer peak wavelength than the second sub color areas when it is exited.

3. The polarized light emissive device (100) according to claim 1, wherein the polarized light emissive device (100) comprises one or more of red sub color areas, green sub color areas and blue sub color areas.

4. The polarized light emissive device (100) according to claim 1, wherein an average alignment direction of the plural of inorganic fluorescent semiconductor quantum rods (120) aligned directly on the surface of the first sub color areas is different from an average alignment direction of the plural of inorganic fluorescent semiconductor quantum rods (120) aligned directly on the surface of the second sub color areas.

5. The polarized light emissive device (100) according to claim 1, wherein the polarized light emissive device (100) further comprises one or more of light shielding areas (140).

6. The polarized light emissive device (100) according to claim 1, wherein the polarized light emissive device (100) further comprises a light reflection medium (150).

7. The polarized light emissive device (100) according to claim 1, wherein the plural of inorganic fluorescent semiconductor quantum rods is covered by one or more of transparent passivation mediums (160).

8. The polarized light emissive device (100) according to claim 1, wherein the plural of inorganic fluorescent semiconductor quantum rods (120) is selected from the group consisting of II-VI, III-V, or IV-VI semiconductors and a combination of any of these, and wherein the plural of inorganic fluorescent semiconductor quantum rods (120) comprises a surface ligand

9. An optical device, comprising in said device the polarized light emissive device (100) according to claim 1.

10. An optical device (170), wherein the optical device (170) includes a polarized light emissive device (100), comprising a substrate (110), and a plural of inorganic fluorescent semiconductor quantum rods (120) directly aligned on the surface of the substrate in a common direction without a binder or matrix, in which the polarized light emissive device embraces one or more of first sub color areas and one or more of second sub color areas (130).

11. Method for preparing the polarized light emissive device (100), wherein the method comprises the following sequential steps of:
(a) dispersing a plural of inorganic fluorescent semiconductor quantum rods into a solvent;
(b) providing the resulting solution from step (a) onto a plural of microgrooves of a polymer substrate; and
(c) transferring the plural of inorganic fluorescent semiconductor quantum rods onto the surface of a substrate or a transfer material, and optionally transferring from the transfer material to a substrate.

12. Method for preparing the polarized light emissive device (100) according to claim 11, wherein the method further comprises following step (e) in step (c);
(e) giving a pressure to the substrate and moving the substrate toward the direction of the long axis of the plural of microgrooves of the polymer substrate under the pressure.

13. Method for preparing the polarized light emissive device (100) according to claim 11, wherein the method further comprises following step (f) in step (b);
(f) applying a sonification to a plural of inorganic fluorescent semiconductor quantum rods.

14. Method for preparing the polarized light emissive device (100) according to claim 11, wherein the method further comprises following steps;
(g) providing a solution having a plural of inorganic fluorescent semiconductor quantum rods onto a plural of microgrooves of a substrate, in which the plural of inorganic fluorescent semiconductor quantum rods in step (g) emits light having different peak wavelength from the plural of inorganic fluorescent semiconductor quantum rods used in step (a) when it is excited by excitation light from a light source; and
(h) transferring the plural of inorganic fluorescent semiconductor quantum rods onto the surface of a transfer material or the substrate of the polarized light emissive device (100).
